(19) United States
(12) Patent Application Publication
(10) Pub. No.: US 2024/0387444 A1
(43) Pub. Date: Nov. 21, 2024

(54) FLIP-CHIP MOUNTING STRUCTURE AND FLIP-CHIP MOUNTING METHOD

(71) Applicant: Panasonic Intellectual Property Management Co., Ltd., Osaka (JP)

(72) Inventors: TAKAHIRO KUMAKAWA, Kyoto (JP); DAISUKE SAKURAI, Osaka (JP)

(21) Appl. No.: 18/786,399

(22) Filed: Jul. 26, 2024

Related U.S. Application Data
(63) Continuation of application No. PCT/JP2023/001556, filed on Jan. 19, 2023.

(30) Foreign Application Priority Data
Feb. 9, 2022 (JP) 2022-018616

(51) Int. Cl. H01L 23/00; H01L 25/065

(52) U.S. Cl. CPC H01L 24/73; H01L 24/13; H01L 24/16; H01L 24/29; H01L 24/32; H01L 24/81; H01L 24/83; H01L 24/92; H01L 25/0657; H01L 2224/13017; H01L 2224/13082; H01L 2224/16145; H01L 2224/16227; H01L 2224/293; H01L 2224/32145; H01L 2224/32227; H01L 2224/32501; H01L 2224/73204; H01L 2224/81201; H01L 2224/83048; H01L 2224/83201; H01L 2224/9211

(57) ABSTRACT

A flip-chip mounting structure includes a first member including a first electrode pad, a bump formed on the first electrode pad, a second member including a second electrode pad, and a connection portion formed on the second electrode pad. The first member and the second member are flip-chip mounted, and the first electrode pad and the second electrode pad are electrically connected via the bump and the bonding portion. The bonding portion includes at least a first bonding portion formed in a region sandwiched between a top portion of the bump and the second electrode pad, and a second bonding portion formed in a region surrounding a periphery of the first bonding portion and a region surrounding at least a side surface of the bump. Each of the first bonding portion and the second bonding portion is made of a sintered body of a metal powder.

### TECHNICAL FIELD

The present invention relates to a flip-chip mounting structure and a flip-chip mounting method.

### BACKGROUND ART

Flip-chip mounting is known as one of techniques for mounting a semiconductor device on a mounting substrate. In the flip-chip mounting, a protrusion electrode is formed on an electrode terminal of a semiconductor device, and is pressed against and heated with respect to an electrode pad of the mounting substrate. Thus, the electrode terminal is bump-connected to the electrode pad of the mounting substrate, and the semiconductor device is flip-chip mounted on the mounting substrate.

Many solder bumps are adopted for the protrusion electrode formed on the electrode terminal. However, as a pitch between electrode terminals is narrowed, a melted and deformed solder bump is connected to the other solder bump due to a surface tension in a pressing and heating step at the time of flip-chip mounting, and a bridge failure is likely to occur.

Thus, a method for adopting a columnar fine metal bump made of, for example, gold or copper instead of the solder bump for the protrusion electrode formed on the electrode terminal has been known. In this method, in the pressing and heating step at the time of flip-chip mounting, a distal end of the protrusion electrode is plastically deformed, and the protrusion electrode is bonded to the electrode pad by solid-phase diffusion. According to this method, since the fine metal bump is not melted in the pressing and heating step at the time of flip-chip mounting, the occurrence of the bridge failure caused by the melting and deformation of the fine metal bump can be prevented.

However, in a case where the semiconductor device is repeatedly used at a high temperature or a low temperature, there arises a problem that a base portion of the fine metal bump is cracked or disconnected due to thermal stress. As a method for solving such a problem, PTL 1 discloses a structure in which a tapered portion is provided at the base portion of the fine metal bump.

### CITATION LIST

### Patent Literature

PTL 1: Unexamined Japanese Patent Publication No. 2014-3201

### SUMMARY OF THE INVENTION

FIG. 11 is a diagram illustrating a structure of the related art when semiconductor device 110 is flip-chip mounted on mounting substrate 120. Electrode pad 111 of semiconductor device 110 and electrode pad 121 of mounting substrate 120 are bonded via metal bump 130. Here, metal bump 130 has a structure including tapered portion 130a and columnar portion 130b.

As illustrated in FIG. 11, a bonding area between electrode pad 121 of mounting substrate 120 and columnar portion 130b of metal bump 130 is smaller than a bonding area between electrode pad 111 of semiconductor device 110 and tapered portion 130a of metal bump 130. Thus, an excessive load is applied to a bonding portion between electrode pad 121 and columnar portion 130b at the time of flip-chip mounting.

Usually, although insulating film 122 is formed under electrode pad 121 of mounting substrate 120, as an electronic component mounted on mounting substrate 120 is miniaturized or transmitted at a high speed, insulating film 122 becomes significantly fragile. Thus, when an excessive load is applied to the bonding portion between electrode pad 121 and columnar portion 130b, a local compressive stress also acts on fragile insulating film 122 under electrode pad 121. When the compressive stress exceeds a breaking stress of insulating film 122, a problem that breakage, a crack, or the like occurs in insulating film 122, or electrical characteristics of a transistor or the like under insulating film 122 and an electronic component fluctuate occurs.

In view of the above problems, an object of the present invention is to provide a flip-chip mounting structure and a flip-chip mounting method capable of alleviating stress applied to a mounting substrate side at the time of flip-chip mounting.

A flip-chip mounting structure according to the present invention includes a first member including a first electrode pad, a bump formed on the first electrode pad, a second member including a second electrode pad, and a connection portion formed on the second electrode pad. The first member and the second member are flip-chip mounted, and the first electrode pad and the second electrode pad are electrically connected via the bump and the bonding portion. The bonding portion includes at least a first bonding portion formed in a region sandwiched between a top portion of the bump and the second electrode pad, and a second bonding portion formed in a region surrounding a periphery of the first bonding portion and a region surrounding at least a side surface of the bump. Each of the first bonding portion and the second bonding portion is made of a sintered body of a metal powder, the sintered body of the first bonding portion is denser than the sintered body of the second bonding portion, and the sintered body of the second bonding portion is porous.

A flip-chip mounting method according to the present invention is a flip-chip mounting method for flip-chip mounting a first member including a first electrode pad and a second member including a second electrode pad. The method includes disposing a bump on the first electrode pad, disposing, on the second electrode pad, a bonding layer in a paste state including a metal powder in a region larger than a diameter of the bump, disposing the first member on the second member, a part of the bump being buried within the bonding layer, converting the bonding layer into a first bonding layer made of a porous sintered body, converting a part of the first bonding layer present between the bump and the second electrode pad into a second bonding layer made of a sintered body denser than the sintered body of the first bonding layer, and connecting the first member and the second member via the bump and the second bonding layer by applying a pressure between the first electrode pad and the second electrode pad.

According to the present invention, it is possible to provide the flip-chip mounting structure and the flip-chip mounting method capable of alleviating the stress applied to the mounting substrate side at the time of flip-chip mounting.

### BRIEF DESCRIPTION OF THE DRAWINGS

FIG. 1 is a sectional view schematically illustrating a flip-chip mounting structure according to a first exemplary embodiment of the present invention.

FIG. 2 is an enlarged view of a region illustrated in A of FIG. 1.

FIG. 3 is a sectional view taken along line B-B′ in FIG. 2.

FIG. 4 is a sectional view schematically illustrating a flip-chip mounting structure according to a modification of the first exemplary embodiment.

FIG. 5 is a sectional view schematically illustrating a flip-chip mounting structure according to another modification of the first exemplary embodiment.

(A) to (D) of FIG. 6 are sectional views schematically illustrating a flip-chip mounting method according to a second exemplary embodiment of the present invention.

(A) and (B) of FIG. 7 are sectional views schematically illustrating the flip-chip mounting method according to the second exemplary embodiment of the present invention.

(A) and (B) of FIG. 8 are diagrams illustrating another exemplary embodiment of a compression step.

(A) and (B) of FIG. 9 are sectional views schematically illustrating a flip-chip mounting method according to a second modification of the second exemplary embodiment.

(A) and (B) of FIG. 10 are sectional views schematically illustrating the flip-chip mounting method according to the second modification of the second exemplary embodiment.

FIG. 11 is a diagram illustrating a structure of the related art when a semiconductor device is flip-chip mounted on a circuit board.

### DESCRIPTION OF EMBODIMENT

Hereinafter, exemplary embodiments of the present invention will be described in detail with reference to the drawings. The present invention is not limited to the following exemplary embodiments. Further, the present invention can be appropriately modified without departing from the scope that provides effects of the present invention.

### First Exemplary Embodiment

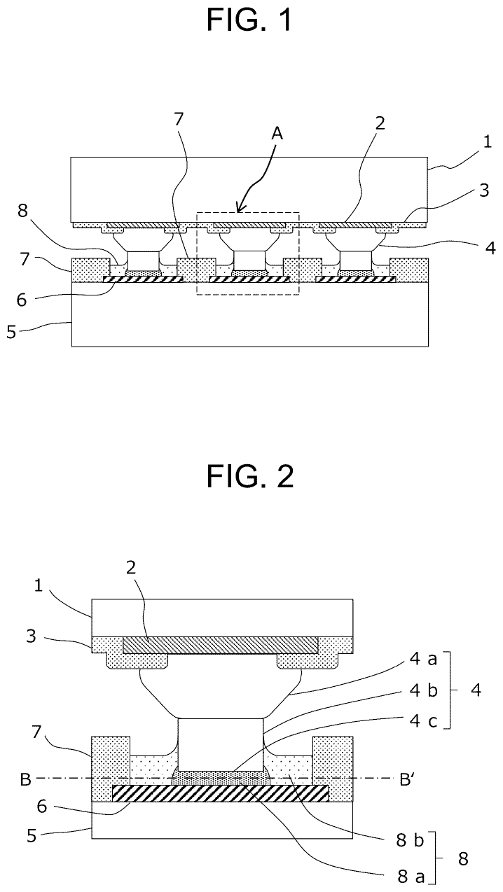

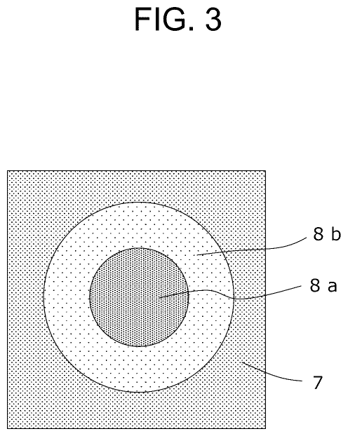

FIG. 1 is a sectional view schematically illustrating a flip-chip mounting structure according to a first exemplary embodiment of the present invention. Further, FIG. 2 is an enlarged view of a region illustrated in A of FIG. 1. Further, FIG. 3 is a sectional view taken along line B-B′ of FIG. 2.

As illustrated in FIG. 1, the flip-chip mounting structure according to the present exemplary embodiment has a structure in which first member 1 including first electrode pads 2 and second member 5 including second electrode pads 6 are flip-chip mounted.

First member 1 and second member 5 according to the present exemplary embodiment are collectively referred to as objects to be flip-chip mounted on each other, and the objects are not particularly limited, and examples thereof include a semiconductor device, a circuit board, an electronic component, a flexible wiring board, and the like.

As illustrated in FIG. 1, first electrode pad 2 and second electrode pad 6 are electrically connected via bump 4 formed on first electrode pad 2 side and bonding portion 8 formed on the second electrode pad side. First electrode pad 2 is exposed at an opening of insulating film 3, and is connected to bumps 4 at the opening. Further, second electrode pad 6 is exposed at an opening of resist 7, and is connected to bonding portion 8 at the opening.

As illustrated in FIG. 2, bump 4 has a structure including tapered portion 4a, columnar portion 4b, and top portion 4c in this order from first electrode pad 2 side. Tapered portion 4a decreases in size from first electrode pad 2 side toward columnar portion 4b. Tapered portion 4a and columnar portion 4b are made of the same material, and there is no interface. Further, top portion 4c indicates a periphery of a distal end of columnar portion 4b, and indicates a lower surface of columnar portion 4b and a side wall portion close to the lower surface. A material of bump 4 is not particularly limited, and examples thereof include copper, cobalt, gold, and silver.

In the present exemplary embodiment, bonding portion 8 is formed of a sintered body of metal powder, and as illustrated in FIGS. 2 and 3, bonding portion 8 includes first bonding portion 8a made of a dense sintered body and second bonding portion 8b made of a porous sintered body. That is, the sintered body of first bonding portion 8a is denser than the sintered body of second bonding portion 8b. First bonding portion 8a is formed at least in a region sandwiched between top portion 4c of bump 4 and second electrode pad 6. Second bonding portion 8b is formed in a region surrounding a periphery of first bonding portion 8a and at least in a region surrounding a side surface of columnar portion 4b of bump 4. First bonding portion 8a and second bonding portion 8b are made of the same material.

Here, the “dense sintered body” refers to a sintered body in a state where bonding between metal powders is dense, voids are few, and the sintered body is close to a bulk metal and the “porous sintered body” refers to a sintered body in a state where bonding between metal powders is rough and voids remain. Naturally, hardness of the “dense sintered body” is larger than hardness of the “porous sintered body”.

A material of bonding portion 8 is not particularly limited as long as the material is a metal powder in which sintering (intermetallic bonding) progresses at a temperature lower than a melting point, and examples thereof include nano metal particles or micro metal particles made of a material such as silver, copper, gold, or solder.

According to the present exemplary embodiment, since bump 4 is connected to second electrode pad 6 via first bonding portion 8a made of a dense sintered body having high rigidity, it is possible to perform strong connection with low electric resistance.

Further, the periphery of first bonding portion 8a is surrounded with second bonding portion 8b made of a porous sintered body having low rigidity, and thus, stress applied to an interface between first bonding portion 8a and top portion 4c of bump 4 and an interface between first bonding portion 8a and second electrode pad 6 can be dispersed. Accordingly, even though an excessive load is applied to bump 4 at the time of flip-chip mounting, stress applied to a fragile insulating film (not illustrated) under second electrode pad 6 can be alleviated. As a result, it is possible to prevent the insulating film from being broken, cracked, or the like, or to prevent electric characteristics of a transistor or the like under the insulating film and an electronic component from varying.

In addition, second bonding portion 8b is formed in the region surrounding the side surface of columnar portion 4b of bump 4, and thus, it is possible to prevent columnar portion 4b from falling down with second bonding portion 8b serving as a support at the time of flip-chip mounting.

Incidentally, in bonding portion 8 illustrated in FIG. 2, a boundary between first bonding portion 8a made of the dense sintered body and second bonding portion 8b made of the porous sintered body is clearly illustrated, but the boundary is not necessarily clear, and may be a region where voids of the sintered body gradually change from a dense region to a porous region. That is, a volume ratio between the voids of the sintered bodies of first bonding portion 8a and second bonding portion 8b may gradually increase from first bonding portion 8a toward second bonding portion 8b. More specifically, the voids of the sintered bodies of first bonding portion 8a and second bonding portion 8b may gradually increase from first bonding portion 8a toward second bonding portion 8b. Further, the number of voids of the sintered bodies of first bonding portion 8a and second bonding portion 8b may gradually increase from first bonding portion 8a toward second bonding portion 8b. Accordingly, an interface between first bonding portion 8a and second bonding portion 8b to which stress is likely to be applied becomes ambiguous, and stress concentration can be alleviated.

In the present exemplary embodiment, in order to further improve reliability, bump 4 has a shape in which tapered portion 4a, columnar portion 4b, and top portion 4c are provided, but the present structure is not particularly limited, and may be, for example, a columnar shape, a spherical shape, or the like.

### Modification of First Exemplary Embodiment

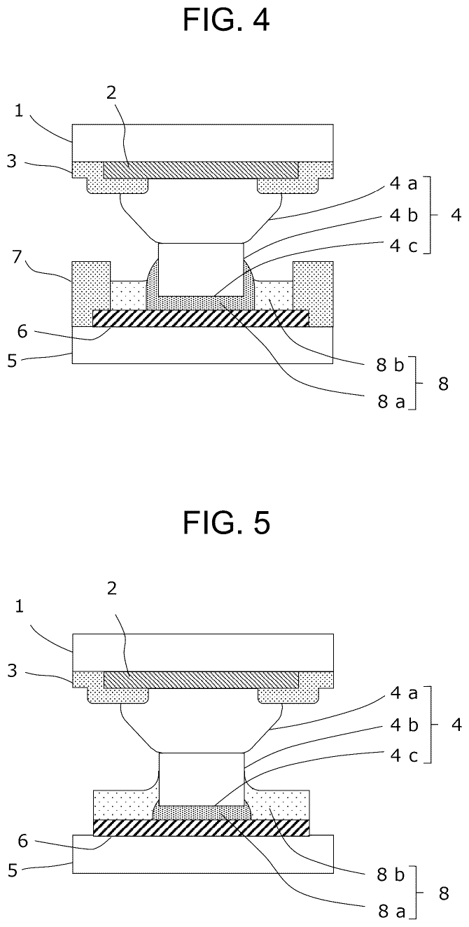

FIG. 4 is a sectional view schematically illustrating a flip-chip mounting structure according to a modification of the first exemplary embodiment.

As illustrated in FIG. 4, in the present modification, a part of first bonding portion 8a made of the dense aggregate is also formed in a region in contact with the side surface of bump 4 (columnar portion 4b). As illustrated in FIG. 2, when the side surface of bump 4 (columnar portion 4b) is in contact with first bonding portion 8a and second bonding portion 8b having different physical properties, stress concentrates on the interface. In the present modification, the side surface of bump 4 (columnar portion 4b) is in contact only with first bonding portion 8a, and thus, stress concentration can be alleviated. Accordingly, a more reliable mounting structure can be obtained.

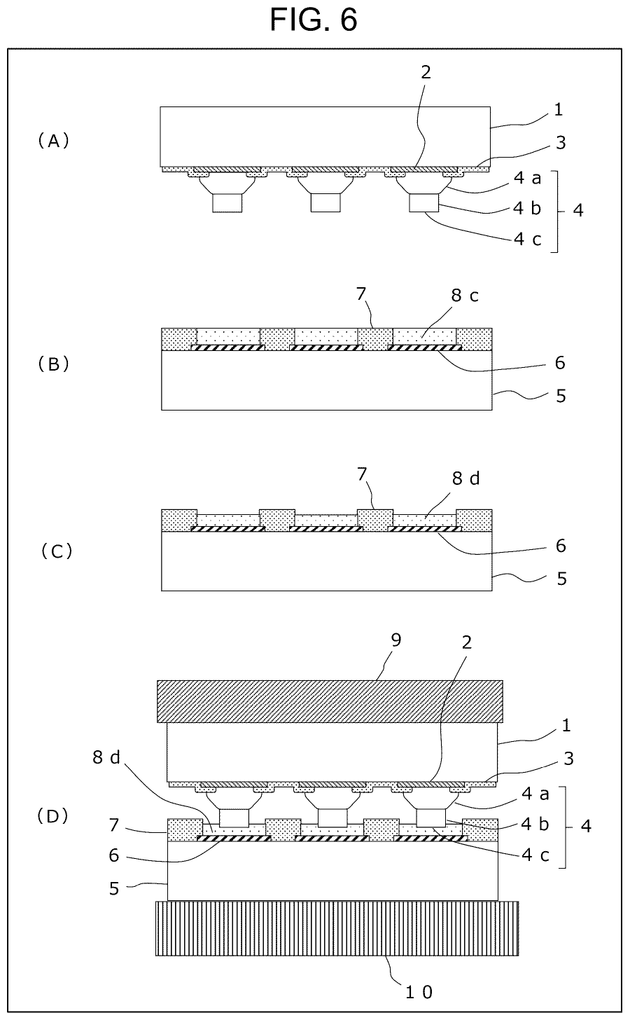

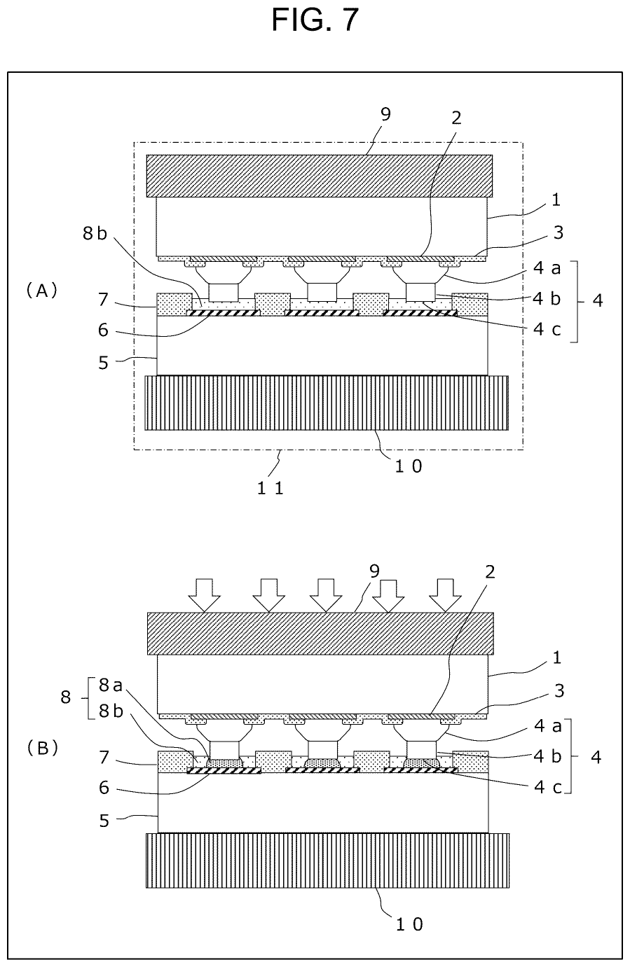

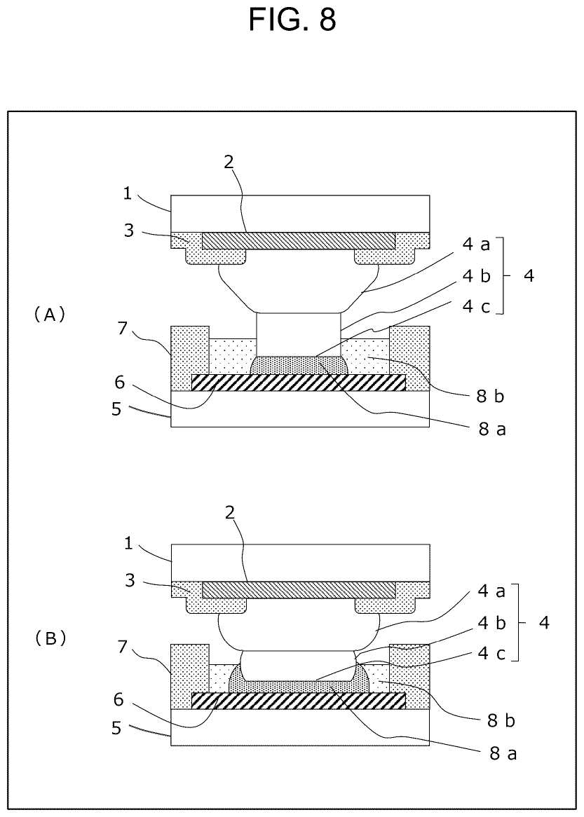

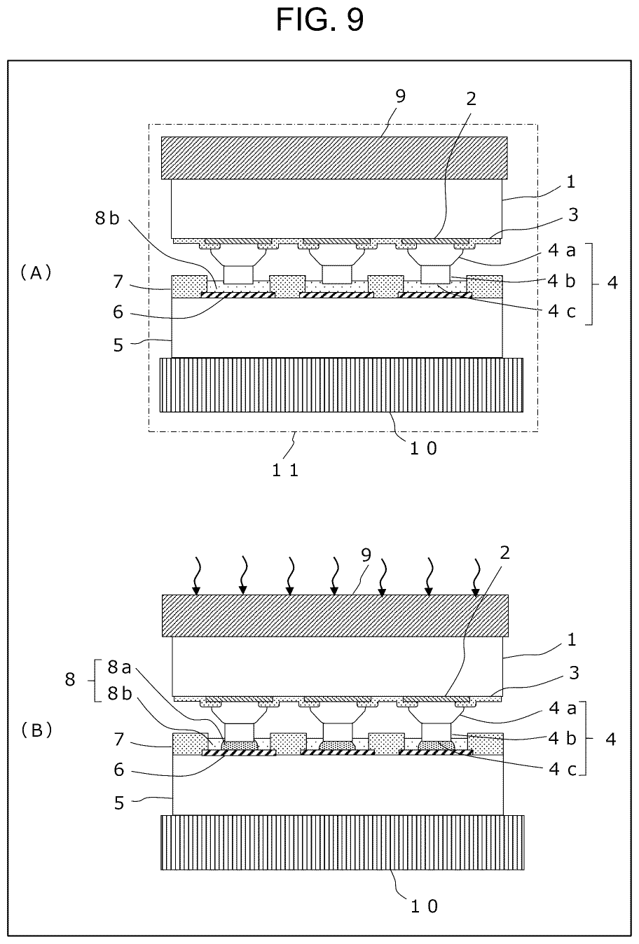

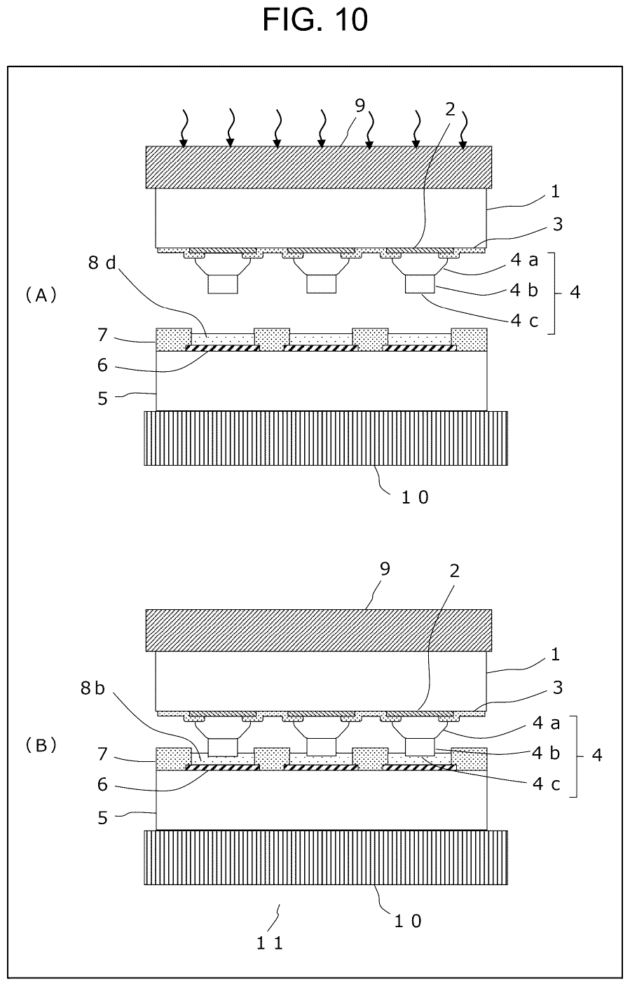

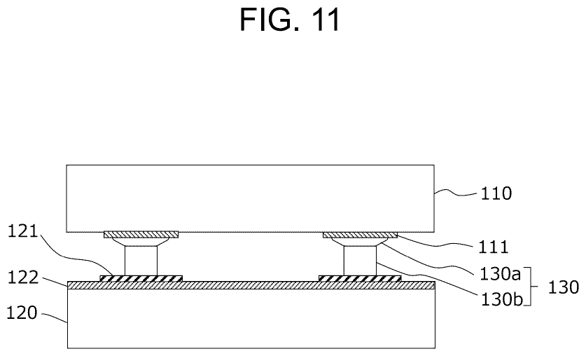

Further, as illustrated in FIG. 5, resist 7 surrounding bonding portion 8 illustrated in FIG. 2 may not be provided.

### Second Exemplary Embodiment

(A) to (D) of FIG. 6 and (A) and (B) of FIG. 7 are sectional views schematically illustrating a flip-chip mounting method according to a second exemplary embodiment of the present invention. In the flip-chip mounting method according to the present exemplary embodiment, first member 1 including first electrode pad 2 and second member 5 including second electrode pad 6 are flip-chip mounted by a method for manufacturing the flip-chip mounting structure illustrated in FIG. 1.

As illustrated in (A) of FIG. 6, bump 4 is formed on first electrode pad 2 formed on a front surface of first member 1. Here, a part of first electrode pad 2 is exposed at an opening formed in insulating film 3. Bump 4 can be formed by a stud bump bonding method, a semi-additive method by plating, a full additive method, or the like.

Subsequently, as illustrated in (B) of FIG. 6, bonding layer 8c in a paste state containing a metal powder is formed in a region larger than a diameter of bump 4 on second electrode pad 6 formed on a front surface of second member 5. Specifically, resist 7 having an opening through which a part of second electrode pad 6 is exposed is formed on second electrode pad 6, and the opening of resist 7 is filled with bonding layer 8c in the paste state. A printing method, a transfer method, or an inkjet method can be used as the filling method. Here, bonding layer 8c is, for example, in a paste state before sintering in which a metal powder is mixed with a dispersant or a solvent.

Subsequently, as illustrated in (C) of FIG. 6, in second member 5, bonding layer 8c in the paste state is heated within a high-temperature furnace or on a hot plate. A heating temperature at this time is a temperature at which only the solvent is vaporized without sintering the metal powder contained in the bonding layer 8c in the paste state. Thus, the bonding layer 8c in the paste state containing the metal powder becomes bonding layer 8d in a temporarily dried state.

This temporary drying step is not necessarily required, and may be omitted.

Subsequently, as illustrated in (D) of FIG. 6, first member 1 adsorbed to collet 9 is disposed on second member 5 held on stage 10 such that a part of bump 4 is buried in bonding layer 8d. At this time, a certain gap is provided between top portion 4c of bump 4 and second electrode pad 6. Further, stage 10 and collet 9 may be preheated in advance.

Subsequently, as illustrated in (A) of FIG. 7, bonding layer 8d in the temporarily dried state is heated to a temperature (first temperature) higher than a sintering temperature of the metal powder to be converted into bonding layer (first bonding layer) 8b made of the porous sintered body.

A method using heat transfer from stage 10, a method of placing entire heating area 11 within a high-temperature furnace, a method using heat transfer from collet 9, a method combining these methods, or the like can be used as the heating method. By this heating step, a sintering reaction of bonding layer 8d in the temporarily dried state progresses, and entire bonding layer 8d is converted into first bonding layer 8b made of the porous sintered body.

Subsequently, as illustrated in (B) of FIG. 7, in first bonding layer 8b, at least a part of first bonding layer 8b present between bump 4 and second electrode pad 6 is converted into bonding layer (second bonding layer) 8a made of the dense sintered body. Specifically, first member 1 is pressed in a direction of second member 5, and a predetermined compressive stress is applied to first bonding layer 8b present between bump 4 and second electrode pad 6. By this compression step, metal bonding between the metal powders further progresses in first bonding layer 8b in a region to which the compressive stress is applied, and first bonding layer 8b in the region is converted into second bonding layer 8a made of the sintered body in a state where voids are few and the sintered body is close to the bulk metal.

Finally, a predetermined pressure is applied between first electrode pad 2 and second electrode pad 6, and thus, first member 1 and second member 5 are connected via bump 4 and first bonding layer 8b to obtain the flip-chip mounting structure illustrated in FIG. 1. Here, first bonding portion 8a and second bonding portion 8b in FIG. 1 correspond to second bonding layer 8a and first bonding layer 8b in the present exemplary embodiment.

The compression step may be performed while gradually increasing the compressive stress applied to first bonding layer 8b. Accordingly, the boundary between second bonding layer 8a made of the dense sintered body and first bonding layer 8b made of the porous sintered body can be a region where the voids of the sintered bodies gradually change from the dense region to the porous region. As a result, the interface between second bonding layer 8a and first bonding layer 8b to which stress is likely to be applied becomes ambiguous, and stress concentration can be alleviated.

Further, as illustrated in (A) and (B) of FIG. 8, the compression step may be performed while plastically deforming bump 4.

As illustrated in (A) of FIG. 8, when the compressive stress is applied to first bonding layer 8b present in a region between bump 4 and second electrode pad 6, first bonding layer 8b present in a region gradually converts into second bonding layer 8a made of the dense sintered body. At this time, the hardness of second bonding layer 8a made of the dense sintered body gradually increases.

When the hardness of second bonding layer 8a increases to some extent, as illustrated in (B) of FIG. 8, bump 4 is gradually plastically deformed, columnar portion 4b gradually collapses, and an area of top portion 4c increases. Accordingly, the region between the portion of widened top portion 4c and second electrode pad 6 also gradually changes to second bonding layer 8a made of the denser sintered body, and the region is widened. Further, since compressive stress is also applied in a side surface direction of columnar portion 4b as bump 4 is crushed, second bonding layer 8a made of the dense sintered body is also formed in the side surface direction of columnar portion 4b. In order to plastically deform bump 4, the hardness of second bonding layer 8a is preferably larger than the hardness of bump 4.

Further, the compression step involving the plastic deformation of bump 4 may also serve as a pressurization step of applying a pressure between first electrode pad 2 and second electrode pad 6 to connect first member 1 and second member 5 via bump 4 and second bonding layer 8a.

### First Modification of Second Exemplary Embodiment

(A) and (B) of FIG. 9 are sectional views schematically illustrating a flip-chip mounting method according to a first modification of the second exemplary embodiment. Since steps illustrated in (A) to (D) of FIG. 6 are the same in the present modification, description thereof is omitted.

In the second exemplary embodiment, although the step of converting first bonding layer 8b into second bonding layer 8a is performed by the compression step of applying the compressive stress to first bonding layer 8b present in the region between bump 4 and second electrode pad 6, in the present modification, this step is performed by a heating step of heating first bonding layer 8b present in the region to a predetermined temperature.

In (A) of FIG. 9, in the same manner as the step illustrated in (A) of FIG. 7, bonding layer 8d in the temporarily dried state is heated to a temperature (first temperature) higher than the sintering temperature of the metal powder to be converted into first bonding layer 8b made of the porous sintered body. The heating here is performed by a method for heating the entire bonding layer 8d in the temporarily dried state.

Subsequently, as illustrated in (B) of FIG. 9, first bonding layer 8b present near a region in contact with bump 4 is heated to a second temperature higher than the first temperature. In order to locally heat the region, it is preferable to heat first member 1 via collet 9 as illustrated in (B) of FIG. 9. Accordingly, first bonding layer 8b present in a region near the region in contact with bump 4 can be locally heated by the heat transferred from first member 1 to bump 4 via first electrode pad 2. By this heating step, the metal bonding between the metal powders further progresses in first bonding layer 8b in the locally heated region, and first bonding layer 8b in the region is converted into second bonding layer 8a made of the sintered body in a state where the voids are few and the sintered body is close to the bulk metal.

After this heating step, a step of applying the compressive stress to second bonding layer 8a present between bump 4 and second electrode pad 6 may be further performed.

### Second Modification of Second Exemplary Embodiment

(A) and (B) of FIG. 10 are sectional views schematically illustrating a flip-chip mounting method according to a second modification of the second exemplary embodiment. Since steps illustrated in (A) to (C) of FIG. 6 are the same in the present modification, description thereof is omitted.

(A) of FIG. 10 is a diagram illustrating a state where first member 1 and second member 5 are disposed such that first electrode pad 2 and second electrode pad 6 face each other.

As illustrated in (A) of FIG. 10, first member 1 is heated to a temperature (first temperature) higher than the sintering temperature of the metal powder via collet 9. Accordingly, the heat from first member 1 is transferred to bump 4 via first electrode pad 2, and a temperature of bump 4 becomes the first temperature. At this time, second member 5 may be heated to a temperature lower than the sintering temperature of the metal powder via stage 10.

Subsequently, as illustrated in (B) of FIG. 10, first member 1 is disposed on second member 5 at a position where a part of bump 4 is buried in bonding layer 8d. Accordingly, bonding layer 8d is gradually heated from the region in contact with bump 4 to the sintering temperature of the metal powder or higher, and entire bonding layer 8d is converted into first bonding layer 8b made of the porous sintered body.

Subsequently, similarly to the case illustrated in (B) of FIG. 7, first member 1 is pressed in the direction of second member 5, and a predetermined compressive stress is applied to first bonding layer 8b present in the region between bump 4 and second electrode pad 6. Accordingly, first bonding layer 8b present in the region is converted into second bonding layer 8a made of the dense sintered body.

Although the present invention has been described heretofore with reference to preferred exemplary embodiments, the above-mentioned descriptions are not limiting items, and it is needless to say that various modifications are conceivable.

### REFERENCE MARKS IN THE DRAWINGS

1 first member
2 first electrode pad
3 insulating film
4 bump
4a tapered portion
4b columnar portion
4c top portion
5 second member
6 second electrode pad
7 resist
8 bonding portion
8a first bonding portion (second bonding layer)
8b second bonding portion (first bonding layer)
8c bonding layer in paste state
8d bonding layer in temporarily dried state
9 collet
10 stage
11 heating area

1. A flip-chip mounting structure comprising:
a first member including a first electrode pad;
a bump disposed on the first electrode pad;
a second member including a second electrode pad; and
a connection portion disposed on the second electrode pad, wherein
the first member and the second member are flip-chip mounted,
the first electrode pad and the second electrode pad are electrically connected via the pad and the bonding portion,
the bonding portion includes at least
a first bonding portion disposed in a region sandwiched between a top portion of the bump and the second electrode pad, and
a second bonding portion disposed in a region surrounding a periphery of the first bonding portion, the region surrounding at least a side surface of the bump,
each of the first bonding portion and the second bonding portion is made of a sintered body of a metal powder,
the sintered body of the first bonding portion is denser than the sintered body of the second bonding portion, and
the sintered body of the second bonding portion is porous.

2. The flip-chip mounting structure according to claim 1, wherein a boundary between the first bonding portion and the second bonding portion is a region where voids of the sintered bodies of the first bonding portion and the second bonding portion gradually change.

3. The flip-chip mounting structure according to claim 1, wherein a part of the first bonding portion is disposed in a region in contact with the side surface of the bump.

4. The flip-chip mounting structure according to claim 1, wherein
the bump includes a tapered portion, and
a sectional area of the tapered portion gradually decreases from the first electrode pad toward the second electrode pad.

5. The flip-chip mounting structure according to claim 1, wherein hardness of the first bonding portion is larger than hardness of the bump.

6. A flip-chip mounting method for flip-chip mounting a first member including a first electrode pad and a second member including a second electrode pad, the method comprising:
disposing a bump on the first electrode pad;
disposing, on the second electrode pad, a bonding layer in a paste state including a metal powder in a region larger than a diameter of the bump;
disposing the first member on the second member, a part of the bump being buried within the bonding layer;
converting the bonding layer into a first bonding layer made of a porous sintered body;
converting a part of the first bonding layer present between the bump and the second electrode pad into a second bonding layer made of a sintered body denser than the sintered body of the first bonding layer; and
connecting the first member and the second member via the bump and the second bonding layer by applying a pressure between the first electrode pad and the second electrode pad.

7. The method according to claim 6, wherein the converting of the bonding layer is performed by heating the bonding layer to a first temperature higher than a sintering temperature of the metal powder.

8. The method according to claim 6, wherein the converting of the part of the first bonding layer is performed by a compression step of applying a compressive stress to a part of the first bonding layer present between the bump and the second electrode pad.

9. The method according to claim 7, wherein the converting of the part of the first bonding layer is performed by a heating step of heating a part of the first bonding layer present between the bump and the second electrode pad to a second temperature higher than the first temperature.

10. The method according to claim 9, wherein the heating step is performed by heat transferred from the first member to the bump by heating the first member.

11. The method according to claim 8, further comprising converting a part of the first bonding layer in contact with the side surface of the bump into the second bonding layer by heat transferred from the first member to the bump by heating the first member after the compression step.

12. The method according to claim 9, further comprising applying a compressive stress to a part of the first bonding layer present between the bump and the second electrode pad after the heating step.

13. The method according to claim 8, wherein the compression step is performed while gradually increasing the compressive stress applied to a part of the first bonding layer.

14. The method according to claim 8, wherein the compressive step is performed while plastically deforming the bump.

15. The method according to claim 14, further comprising a step of converting a part of the first bonding layer in contact with the side surface of the bump into the second bonding layer by a compressive stress in a side surface direction of the bump involving the plastic deformation of the bump.
